(19) United States
(12) Patent Application Publication
(10) Pub. No.: US 2021/0188609 A1
(43) Pub. Date: Jun. 24, 2021

(54) PROXIMITY SENSOR ASSEMBLY

(71) Applicant: TEREX SOUTH DAKOTA, INC., Watertown, SD (US)

(72) Inventors: James A. DONALDSON, Puyallup, WA (US); Michael P. DOENLEN, Kirkland, WA (US); Jerry A. DE VERA, Renton, WA (US); Michael G. FLANAGAN, Seattle, WA (US); John W. WILLIAMS, Seattle, WA (US); Mohd Hafizul ABDULLAH SUHAIMI, Monroe, WA (US)

(73) Assignee: TEREX SOUTH DAKOTA, INC., Watertown, SD (US)

(21) Appl. No.: 17/053,645

(22) PCT Filed: May 7, 2019
(86) PCT No.: PCT/US2019/031050

§ 371 Date: Nov. 6, 2020

Related U.S. Application Data
(60) Provisional application No. 62/762,502, filed on May 7, 2018.

(51) Int. Cl. B66F 17/00; B66F 11/04; H03K 17/945

(52) U.S. Cl. CPC B66F 17/006; H03K 17/945; B66F 11/042

(57) ABSTRACT

A proximity sensor assembly according to the disclosure includes a detection member, a switch, and a movable mounting arrangement associated with the detection member and the switch. The movable mounting arrangement includes a biasing characteristic for urging the detection member toward a home position after the detection member has been displaced from the home position, and a dampening characteristic to dampen movement of the detection member. Furthermore, the switch is actuatable when the detection member is displaced from the home position.

### CROSS-REFERENCE TO RELATED APPLICATIONS

This application claims the benefit of U.S. provisional application Ser. No. 61,762,502 filed May 7, 2018, the disclosure of which is hereby incorporated in its entirety by reference herein.

### TECHNICAL FIELD

The invention relates to a proximity sensor assembly, a mobile work platform including such a sensor assembly, and a vehicle including such a sensor assembly.

### BACKGROUND

Examples of safety devices for mobile work platforms are disclosed in U.S. Patent Application Publication Number 2013/0233645 A1 and U.S. Patent Application Publication Number 2015/0008073 A1.

### SUMMARY

A proximity sensor assembly according to the disclosure may include a detection member, a switch, and a movable mounting arrangement associated with the detection member and the switch. The movable mounting arrangement may include a biasing characteristic for urging the detection member toward a home position after the detection member has been displaced from the home position, and a dampening characteristic for dampening movement of the detection member. Furthermore, the switch is actuatable when the detection member is displaced from the home position.

According to at least one embodiment of the disclosure, a mobile work platform assembly is provided for use with a movable support assembly that is configured to move the mobile work platform assembly. The mobile work platform assembly may include a work platform sized to receive an operator, a control arrangement associated with the work platform for controlling movement of the work platform, and a proximity sensor assembly associated with the work platform. The proximity sensor assembly may include a detection member, an actuatable switch, and a movable mounting arrangement associated with the detection member and the switch. The movable mounting arrangement may include a biasing characteristic for urging the detection member toward a home position after the detection member has been displaced from the home position and a dampening characteristic to dampen movement of the detection member. Furthermore, when the detection member is displaced from the home position, the switch is actuatable to inhibit operation of the control arrangement.

A vehicle according to the disclosure may include a vehicle body, a support assembly connected to the vehicle body, and a mobile work platform assembly supported by the support assembly so that the work platform assembly is movable with respect to the vehicle body. The work platform assembly may include a work platform sized to receive an operator, a control arrangement associated with the work platform for controlling movement of the work platform, and a proximity sensor assembly associated with the work platform. The proximity sensor assembly may include a detection member, an actuatable switch, and a movable mounting arrangement associated with the detection member and the switch. The mounting arrangement may include a biasing characteristic for urging the detection member toward a home position after the detection member has been displaced from the home position, and a dampening characteristic for dampening movement of the detection member. When the detection member is displaced from the home position, the switch is actuatable to inhibit operation of the control arrangement.

While exemplary embodiments are illustrated and disclosed, such disclosure should not be construed to limit the claims. It is anticipated that various modifications and alternative designs may be made without departing from the scope of the disclosure.

### BRIEF DESCRIPTION OF THE DRAWINGS

FIG. 1 is a perspective view of a vehicle including a mobile work platform assembly according to the present disclosure, and multiple proximity sensor assemblies attached to the work platform assembly;

FIG. 2 is a fragmentary cross-sectional view of one of the proximity sensor assemblies with a detection member shown in a home position;

FIG. 3 is a fragmentary cross-sectional view of the proximity sensor assembly of FIG. 2 with the detection member shown in a displaced position, with a cover of the proximity sensor assembly removed;

FIG. 4 is an exploded perspective view of the proximity sensor assembly shown in FIG. 2;

FIG. 5 is an enlarged perspective view of a base of the proximity sensor assembly including a circular insert for facilitating mounting of the proximity sensor assembly on a round rail or other feature of the work platform assembly;

FIG. 6 is an enlarged perspective view of the base of the proximity sensor assembly including a flat-sided insert for facilitating mounting of the proximity sensor assembly on a a rail or other feature having a rectangular cross-section;

FIG. 7 is an enlarged exploded fragmentary perspective view of a portion of the proximity sensor assembly showing the detection member and a detection member holder that receives the detection member, wherein the detection member and the detection member holder include mounting features for orienting the detection member with respect to the detection member holder;

FIG. 8 is a perspective view or a second embodiment of a proximity sensor assembly according to the disclosure; and

FIG. 9 is a fragmentary cross-sectional view of the proximity sensor assembly of FIG. 8.

### DETAILED DESCRIPTION

As required, detailed embodiments are disclosed herein. However, it is to be understood that the disclosed embodiments are merely exemplary, and that various and alternative forms may be employed. The figures are not necessarily to scale; some features may be exaggerated or minimized to show details of particular components. Therefore, specific structural and functional details disclosed herein are not to be interpreted as limiting, but merely as a representative basis for teaching one skilled in the art.

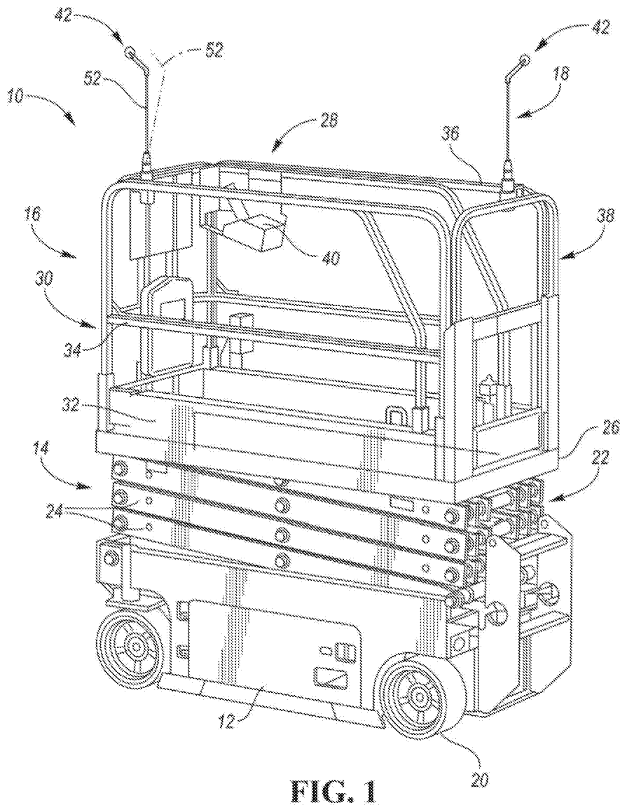

FIG. 1 shows a vehicle 10, according to the present disclosure, including a vehicle body 12, a support assembly 14 connected to the vehicle body 12, and a mobile work platform assembly 16 supported by the support assembly 14 so that the work platform assembly 16 is provided with an movable with respect to the vehicle body 12. The work platform assembly 16 is provided with an obstruction proximity sensing system 18, according to the disclosure, for sensing potential obstructions to the work platform assembly 16 during operation of the work platform assembly 16, as explained below in detail.

The vehicle 10 may be any suitable vehicle, such as a boom lift, scissor lift, or any other suitable aerial lift. Furthermore, the vehicle body 12 may be supported on any suitable support members 20, such as one or more tires, tracks, outriggers, etc. In the embodiment shown in FIG. 1, the vehicle body 12 is supported on multiple tires, two or more of which may be steerable.

The support assembly 14 likewise may be any suitable support assembly, such as a lift arm, vertical mast, articulating boom assembly, telescopic boom assembly, scissor lift assembly, etc. In the embodiment shown in FIG. 1, the support assembly 14 comprises a scissor lift 22 having multiple sections 24 that are movable relative to each other to move the work platform assembly 16 between a lowered position and a raised position (not shown).

The work platform assembly 16 includes a base or work platform 26 and a control arrangement 28 associated with the platform 26 for controlling movement of the platform 26. In addition, the work platform assembly 16 includes the above-mentioned obstruction proximity sensing system 18, which is also associated with the platform 26 and the control arrangement 28.

The platform 26 of the work platform assembly 16 is sized to receive an operator thereon. A railing assembly or frame assembly 30 is provided on the platform 26, and the frame assembly 30 includes one or more guard rails that cooperate to contain the operator within the frame assembly 30. In the embodiment shown in FIG. 1, the frame assembly 30 includes multiple toe boards 32, middle rails 34 and top rails 36. The frame assembly 30 further includes a movable (e.g., pivotable) door 38 to allow or permit operator ingress to, and egress from, the work platform assembly 16.

The control arrangement 28 may include any suitable controls for controlling operation of the platform 26 (e.g., movement of the platform 26). For example, the control arrangement 28 may include a control unit 40 (e.g., electronic control unit, control box or control panel) having one or more controls, such as buttons, switches, levers (e.g., joysticks), etc., for inputting control commands.

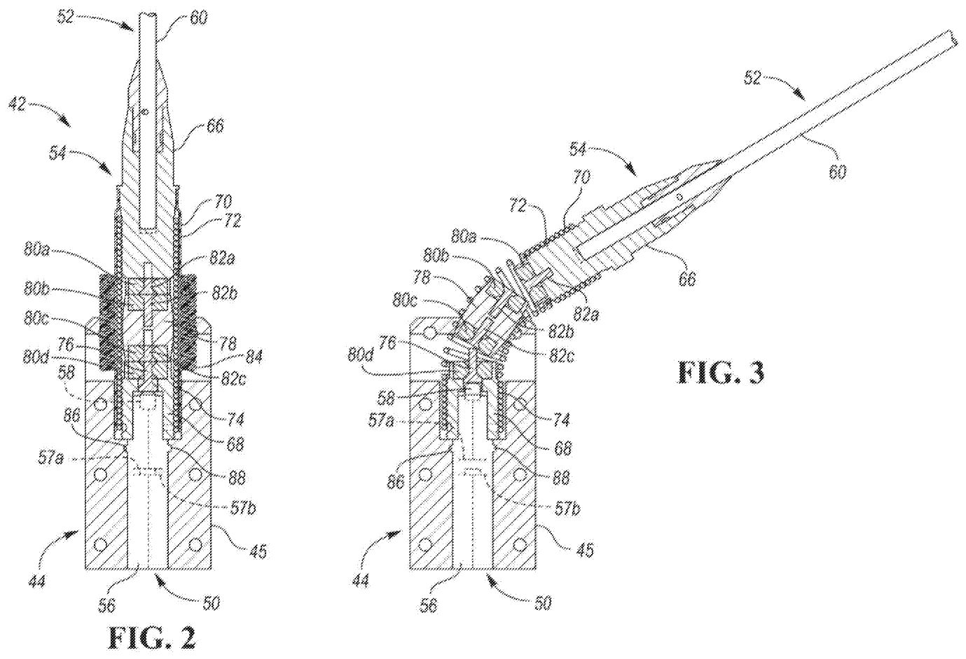

The above-mentioned obstruction proximity sensing system 18 is associated with the platform 26 and the control arrangement 28, and includes one or more proximity sensor assemblies 42 that are configured to sense presence of an obstruction when the work platform assembly 16 is moved. The one or more proximity sensor assemblies 42 may also be electrically connected to the control arrangement 28, e.g., to the control unit 40. Details of one of the proximity sensor assemblies 42 will now be described with reference to FIGS. 2-4, with the understanding that any other proximity sensor assemblies 42 may have the same or similar configuration.

The proximity sensor assembly 42 shown in FIGS. 2-4 includes a base 44, such as an assembly mount, that is mountable onto a rail (e.g., a top rail 36) or other feature of the work platform assembly 16. In the illustrated embodiment, the base 44 includes a first section or portion 45 that is attachable to the work platform assembly 16, and a second section or portion 46 that is attachable to the first portion 45 with one or more fasteners, such as bolts or screws.

Referring to FIGS. 5 and 6, the first portion 45 may include a main body 47, an insert 48 that is receivable in an opening or recess formed in the main body 47 for facilitating installation of the first portion 45 on a rail (e.g, top rail 36 of the frame assembly 30) or other feature of the work platform assembly 16, and a retainer 49, such as an end plate, that is attachable to the main body 47 with any suitable fasteners (e.g., bolts or screws) to help retain the insert 48 in the recess of the main body 47 when the first portion 45 is mounted on the rail or other feature of the work platform assembly 16. In the embodiment shown in FIG. 5, the first portion 45 includes a cylindrical insert 48a having a cursed inner surface, such as a circular inner surface viewed in cross-section, that is configured to mate with a round rail or other feature of the work platform assembly 16. In the embodiment shown in FIG. 6, the first portion 45 includes an insert 48b having flat inner sides or surfaces, such as a C-shaped insert having three flat inner sides or surfaces, that are configured to mate with a rail or other feature of the work platform assembly 16 having a rectangular cross-section (e.g., square cross-section). Furthermore, each insert 48a, 48b may be formed as a single piece or multiple pieces, and each piece may be separately attachable to the main body 47, such as with any suitable fasteners (e.g., bolts or screws).

Returning to FIGS. 2-4, the proximity sensor assembly 42 further includes a switch 50, such as a limit switch, cut-off switch, etc., received in the base 44; a detection member, such as a wand assembly 52, for sensing obstructions; and a movable mounting arrangement 54 associated with (e.g., connected to) the base 44 and the switch 50. In the illustrated embodiment, the mounting arrangement 54 connects the wand assembly 52 to the base 44 and the switch 50 so that the wand assembly 52 is movable with respect to the base 44. Furthermore, as explained below in further detail, the mounting arrangement 54 includes a biasing characteristic for urging the wand assembly 52 toward a home position, and a damping characteristic for dampening movement of the wand assembly 52.

Referring to FIGS. 2 and 3, the switch 50 (e.g., limit switch) may include a switch body 56 that houses a set of contacts 57a and 57b, and an actuator, such as a spring-loaded button 58, that is movable with respect to the switch body 56 and mechanically linked to one or both of the contacts 57a and 57b (the switch 50 is not shown in cross-section in FIGS. 2 and 3). In the illustrated embodiment, the button 58 is linked to the upper contact 57b and movable with the upper contact 57b. When the button 58 is moved away from the switch body due to force of the associated spring (not shown), the switch 50 is actuated so that the contacts 57a and 57b are separated from each other.

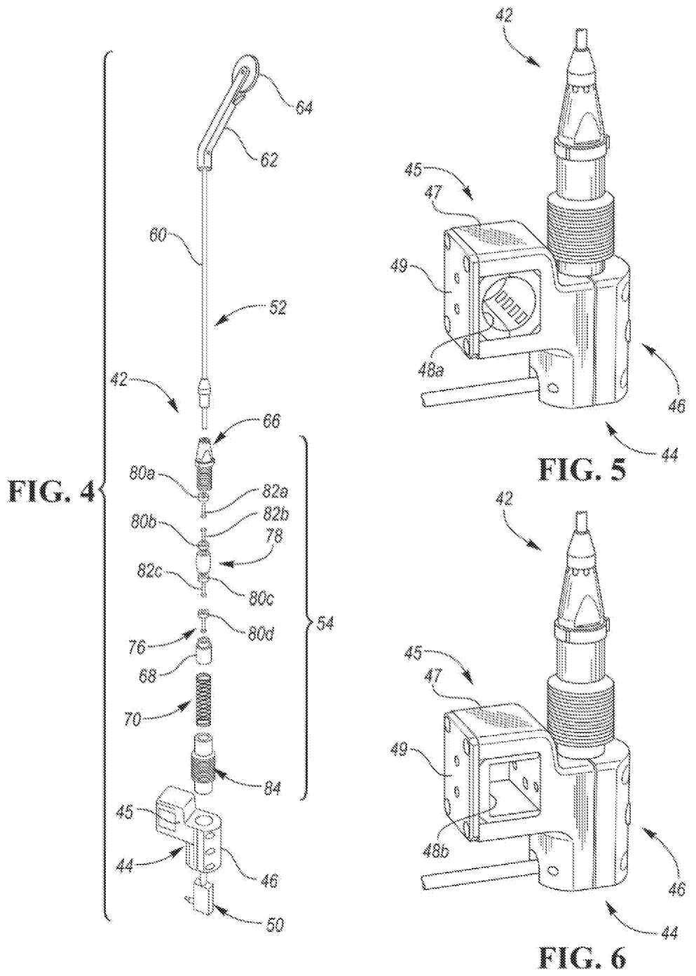

Referring to FIG. 4, the wand assembly 52 may include a main body portion 60 and an angled head portion 62 attached to the main body portion 60. The wand assembly 52 may further include a rotatable member, such as a wheel 64, rotatably attached to the head portion 62. With such a configuration, the wand assembly 52 may make contact with an obstruction prior to the platform 26 of the work platform assembly 16 being laterally aligned with the obstruction. Furthermore, the wheel 64 or other rotatable member may facilitate smooth contact with the obstruction and inhibit undesired bending of the main body portion 60 of the wand assembly 52.

Referring to FIGS. 2-4, the mounting arrangement 54 may include a detection member holder or wand assembly holder 66 connected to the wand assembly 52 in any suitable manner (e.g., with a set screw), a mounting member or mount 68 connected to the switch 50 in any suitable manner (e.g., threadingly connected together), and a biasing member, such as a cylindrical spring member 70, associated with the wand assembly holder 66 and the mount 68 and that provides the biasing characteristic. The spring member 70 is also configured to allow the wand assembly holder 66 and the wand assembly 52 to move with respect to the mount 68. In the illustrated embodiment, the spring member 70 is connected to the wand assembly holder 66 and the mount 68 in any suitable manner. For example, the wand assembly holder 66 may include a threaded portion 72, the mount 68 may include a threaded portion 74, and the spring member 70 may be a coil, extension spring that is connected to the threaded portions 72 and 74, such as by rotating the spring member 70 and/or the threaded portions 72 and 74 relative to each other. Furthermore, the mount 68 may be formed integrally with at least a portion of the base 44.

The mounting arrangement 54 may further include an engaging member such as a plunger 76 that extends into the mount 68 for engaging the button 58 of the switch 50, and a spacer member or intermediate member 78 positioned between the wand assembly holder 66 and the mount 68. In addition, the mounting arrangement 54 includes one or more damping members, such as magnets 80, that provide the damping characteristic for damping movement of the wand assembly 52.

In the illustrated embodiment, the mounting arrangement 54 includes first, second, third and fourth magnets 80a, 80b, 80c and 80d, respectively. The first magnet 80a is attached to the wand assembly holder 66 with a first fastener 82a, such as, a screw. The second magnet 80b is attached to the intermediate member 78 with a second fastener 82b, such as a screw. The third magnet 80c is attached to the intermediate member 78 with a third fastener 82c, such as a screw. The fourth magnet 80d is attached to the mount 65 via an interference fit, and the fourth magnet 80d receives an end of the plunger 76 so that the plunger 76 is movable with respect to the fourth magnet 80d. The third fastener 82c also holds the plunger 76 in a depressed position shown in FIG. 2, so that the plunger 76 pushes against the spring force of the button 58 and holds the button 58 in a depressed position. Furthermore, the first and second magnets 80a and 80b, respectively, are oriented so that they are attracted to each other, and the third and fourth magnets 80c and 80d, respectively, are oriented so that they are also attracted to each other.

In another embodiment, the mount arrangement 54 may include a single pair of magnets. For example, in such an embodiment, the mounting arrangement 54 may include the above-described third and fourth magnets 80c and 80d, respectively but not the first and second magnets 80a and 80b, respectively.

The mounting arrangement 54 may further include a cover 84 that covers one or more of the other components of the mounting arrangement. In the illustrated embodiment, the cover 84 is positioned over the intermediate member 78 and magnets 80a-80d to inhibit dirt, moisture and/or debris from contacting the magnets 80a-80d.

Referring to FIGS. 1-4, operation of the vehicle 10 will now be described in further detail. When the vehicle 10 is located in a desired position and suitably supported or otherwise braced, the operator may enter the work platform assembly 16 through the door 38. The operator may then move the work platform assembly 16 using the control unit 40. The work platform assembly 16 may first require that the operator activate an enabling element, so that the control unit 40 may be operated to move the work platform assembly 16 and in order to activate the obstruction proximity sensing system 18. For example, the work platform assembly 16 may include a foot-switch (not shown) that the operator may step on in order to allow operation of the control unit 40 and the obstruction proximity sensing system 18.

The operator may move the work platform assembly 16 as desired using the controls of the control unit 40. For example, the controls may be used to control movement of the support assembly 14 and/or movement of the work platform assembly 16 with respect to the support assembly 14. While the work platform assembly 16 is in motion, one or more of the proximity sensor assemblies 42 of the obstruction proximity sensing system 18 may detect presence of one or obstructions by contacting the one or more obstructions.

Referring to FIGS. 1-3, when the wand assembly 52 of a particular proximity sensor assembly 42 contacts an obstruction, the movable mounting arrangement 54 is configured to allow the wand assembly 52 to move with respect to the base 44 and the switch 50 from a home position (shown in solid lines on the left side of FIG. 1, and in FIG. 2) to a displaced position (shown in phantom lines on the left side of FIG. 1, and in FIG. 3). For example, referring to FIG. 3, if the force on the wand assembly 52 is sufficient, the spring member 70 may flex or otherwise move to allow the wand assembly holder 66 to move with respect to the base 44 and the switch 50 so that the first magnet 80a separates from the second magnet 80b, and so that the third magnet 80c separates from the fourth magnet 80d. As a result, the third fastener 82c associated with the third magnet 80c may likewise move away from the fourth magnet 80d to allow the plunger 76 and the button 58 of the switch 50 to move sufficiently away from the switch body 56 of the switch 50, due to urging by the spring associated with the button 58, thereby actuating the switch 50 (e.g., separating the contacts 57a and 57b of the switch 50). The switch 50, which may be connected to the control arrangement 28 of the work platform assembly 16, may then cause the control arrangement 28 to shut down. For example, actuation of the switch 50 may cause electrical power to be disconnected from the control unit 40 of the control arrangement 28. The vehicle 10 may also include a control (e.g., button, switch, lever, etc.) that may be actuated or otherwise activated to override the switch 50 and return power to the control unit 40 or other portion of the control arrangement 28. For example, the control unit 40 may include an override control that may be actuated to restore power.

When the wand assembly 52 is no longer contacting the obstruction, the spring member 70 urges the wand assembly 52 back toward the home position shown in FIG. 2. Furthermore, the magnets 80a-80d may advantageously function to limit over-travel of the wand assembly 52 as the wand assembly 52 returns to the home position. For example, the magnets 80a-80d may be configured to limit over-travel of the wand assembly 52 beyond the home position to less than 20% of the displaced distance when the wand assembly 52 is moved from the displaced position to the home position and then beyond the home position due to whipping motion of the wand assembly 52. In that regard, the first and second magnets 80a and 80b, respectively, are drawn toward each other, and the third and fourth magnets 80c and 80d, respectively, are drawn toward each other, so that the wand assembly 52 is inhibited from moving significantly beyond the home position when the and assembly 52 is urged toward the home position. The magnets 80a-80d may also inhibit the wand assembly 52 from oscillating between the home position and the displaced position. The magnets 80a-80d may therefore act as damping members that provide an anti-whipping function for the wand assembly 52.

When the magnets of the magnet pairs 80a-80b and 80c-80d are separated from each other, the intermediate member 78 is movably retained by the spring member 70. In such case, the intermediate member 78 may be considered to “float” in a space defined by the spring member 70. Furthermore, the intermediate member 78 and the second and third magnets 80b and 80c, respectively, may together be considered an intermediate magnet assembly or mid-magnet assembly.

Furthermore, use of two magnet pairs 80a, 80b and 80c, 80d and the intermediate member 78 (i.e., floatable segment) may enable softer movement damping of the wand assembly 52 compared with a single magnet pair. Furthermore, the strength of the magnets may be selected so that only one magnet pair separates at a time. For example, the strength of attraction of the third and fourth magnets 80c and 80d, respectively, may be less than the strength of attraction of the first and second magnets 80a and 80b, respectively, so that the third and fourth magnets are configured to separate before the first and second magnets separate. With such a configuration, the switch 50 may be actuated when the wand assembly 52 is only slightly displaced. Furthermore, continued displacement of the wand assembly 52 may cause the first and second magnets 80a and 80b, respectively, to separate to prevent or inhibit damage to the wand assembly 52.

Although the wand assembly 52 may be connected to the wand assembly holder 66 in any suitable manner as mentioned above, use of a set screw may allow the wand assembly 52 to be fixed in any suitable orientation with respect to the wand assembly holder 66. With such a configuration, the and assembly 52 may be positioned (e.g., rotated) with respect to the wand assembly holder 66 to achieve a desired orientation with respect to potential obstructions, and then the wand assembly 52 may be secured in that orientation with the set screw.

Referring to FIGS. 2-6, the first and second portions 45 and 46, respectively, of the base 44 may sandwich the switch 50, mount 68 and spring member 70 therebetween when the portions 45 and 46 are connected together to provide secure attachment between the base 44 and the rest of the proximity sensor assembly 42. Furthermore, one or both portions 45, 46 may include a mounting feature that cooperates with the switch 50 to hold the switch 50 securely in place. In the embodiment shown in FIGS. 2 and 3, the second portion 46 includes one or more recesses 86 that each receive a projection 88, such as a ridge, formed on the switch body 56 of the switch 50.

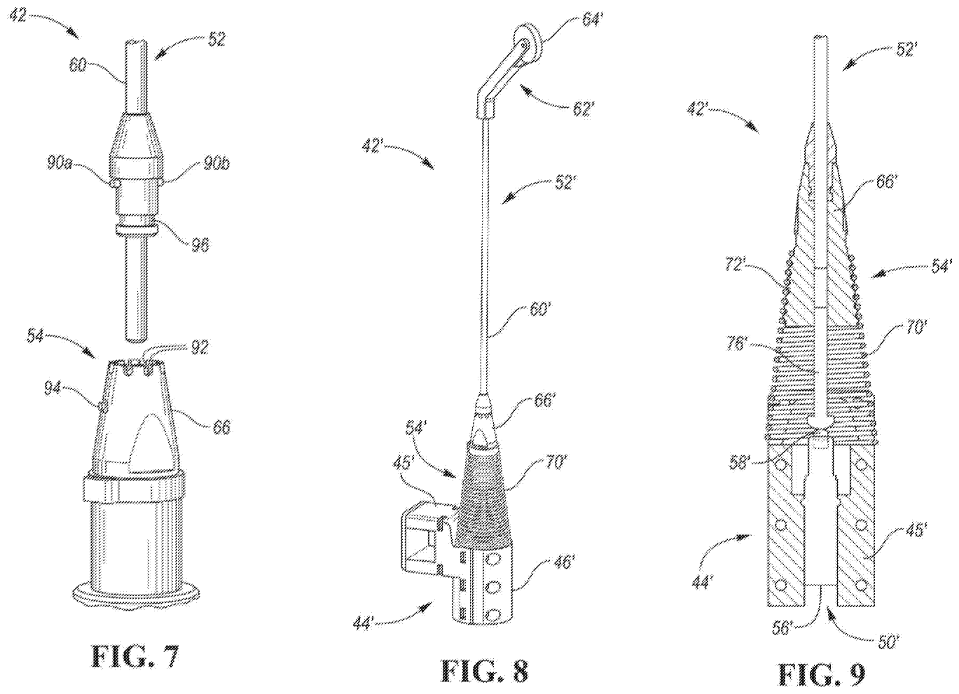

Referring to FIG. 7, additional details of an embodiment of the proximity sensor assembly 42 will now be described for orienting the wand assembly 52 with respect to the wand assembly holder 66. For example, one of the wand assembly 52 and the wand assembly holder 66 may include one or more projections (e.g., at least two projections) that are each selectively receivable in one of multiple notches or slots formed in the other of the wand assembly 52 and the wand assembly holder 66 so that the wand assembly 52 may be oriented in any one of multiple orientations with respect to the wand assembly holder 66. As a more specific example, one of the wand assembly 52 and the wand assembly holder 66 may include two projections that are selectively receivable in two of multiple slots (e.g., at least four slots) formed in the other of the wand assembly 52 and the wand assembly holder 66. In the illustrated embodiment, the wand assembly 52 includes two projections 90a and 90b, and the wand assembly holder 66 includes eight slots 92 for selectively receiving the projections 90a and 90b. Furthermore, the projections 90a and 90b are spaced apart by 180° center to center, and the slots 92 are spaced equally about a perimeter of the wand assembly holder 66 so that adjacent slots 92 are spaced apart by 45° center to center. With such a configuration, position of the wand assembly 52 may be adjusted in 45° increments with respect to the wand assembly holder 66 and/or platform 26 in order to position the angled head portion 62 of the wand assembly 52 in a desired orientation with respect to the wand assembly holder 66 and/or platform 26. Once a desired orientation has been selected, the wand assembly 52 may be connected to the wand assembly holder 66 in any suitable manner, such as with a set screw 94 that extends through an opening in the wand assembly holder 66 and into a notch or grove 96 (e.g., circumferential groove) formed in the main body portion 60 of the wand assembly 52.

Referring to FIGS. 8 and 9, a second embodiment 42′ of a proximity sensor assembly is shown. The proximity sensor assembly 42′ includes various similar features as the proximity sensor assembly 42, and those similar features are identified with the same reference numbers, except the similar reference numbers in FIGS. 8 and 9 each include a prime mark. Therefore, the following description will primarily focus on the differences between the proximity sensor assembly 42′ and the proximity sensor assembly 42. In that regard, the proximity sensor assembly 42′ includes a simplified movable mounting arrangement 54′ associated with (e.g., connected to) switch 50′ (e.g., limit switch, cut-off switch, etc.) and a detection member, such as wand assembly 52′. In the illustrated embodiment, the mounting arrangement 54′ includes a detection member holder, such as wand assembly holder 66′, connected to the wand assembly 52′, and a biasing member, such as a spring member 70′, associated with base 44′, the switch 50′ and the wand assembly holder 66′. Furthermore, the spring member 70′ is configured to provide a biasing characteristic for urging the wand assembly 52′ toward a home position, shown in FIGS. 5 and 6, and a damping characteristic for damping or dampening movement of the wand assembly 52′, as explained below in greater detail. For example, the spring member 70′ may be a conically-shaped, coil extension spring.

In the illustrated embodiment, the spring member 70′ is connected to the base 44′ and the wand assembly holder 66′. For example, the base 44′ may include a threaded portion (not shown), the wand assembly holder 66′ may include a threaded portion 72′, and the spring member 70′ may be a coil, extension spring that is connected to the threaded portions, such as by rotating the spring member 70′ and/or the base 44′ and wand assembly holder 66′ relative to each other. As another example, the spring member 70′ may be connected to the base 44′ and/or the wand assembly holder 66′ with suitable fasteners, such as clamps.

The mounting arrangement 54′ further includes an engaging member, such as a plunger 76′, that is fixedly connected to the wand assembly holder 66′ and engageable with an actuator, such as a spring-biased button 58′, of the switch 50′. When the wand assembly 52′ is in the home position shown in FIGS. 8 and 9, the plunger 76′ pushes against the spring force of the button 58′ and holds the button 58′ in a depressed position. When the wand assembly 52′ is moved to a displaced position similar to that shown in FIG. 3, due to contact with an obstruction for example, the plunger 76′ may move sufficiently away from switch body 56′ of the switch 50′, so that the button 58′ may likewise move away from the switch body 56′ to actuate the switch 50′. The switch 50′, which may be connected to the above-mentioned control arrangement 28 of the work platform assembly 16, may then cause the control arrangement 28 to shut down. For example, actuation of the switch 50′ may cause electrical power to be disconnected from the control unit 40 of the control arrangement 28.

When the wand assembly 52′ is no longer contacting the obstruction, the spring member 70′ urges the wand assembly 52′ back toward the home position shown in FIGS. 8 and 9. Furthermore, the conical shape of the spring member 70′ may advantageously function to limit over-travel of the wand assembly 52′ as the wand assembly 52′ returns to the home position. For example, the spring member 70′ may concentrate spring force toward the wand assembly holder 66′ and wand assembly 52′, due to the spring member 70′ being tapered toward the wand assembly holder 66′ and wand assembly 52′, so that the wand assembly 52′ is urged more quickly to the home position as compared to a cylindrical coil spring. The spring member 70′ may provide a biasing characteristic as weal as a dampening characteristic.

It should be noted that features of any of the above embodiments may be combined together to form other embodiments according to the disclosure. For example, the proximity sensor assembly 42 may be provided with a conically-shaped spring member, instead of a cylindrically shaped spring member. As another example, the proximity sensor assembly 42′ may include at least one damping member, in addition to the spring member 70′, to dampen movement of the wand assembly 52′. In that regard, the proximity sensor assembly 42′ may include at least one magnet or other magnet arrangement, such as described above with respect to the proximity sensor assembly 42.

The below paragraphs describe general aspects that may be included in embodiments according to the disclosure.

A proximity sensor assembly according to the disclosure may include a detection member, a switch, and a movable mounting arrangement associated with the detection member and the switch. The movable mounting arrangement may include a biasing characteristic for urging the detection member toward a home position after the detection member has been displaced from the home position, and a dampening characteristic for dampening movement of the detection member. Furthermore, the switch is actuatable when the detection member is displaced from the home position.

The mounting arrangement of the proximity sensor assembly may include an extension spring to provide the biasing characteristic. The mounting arrangement may comprise a conical spring that provides the biasing characteristic and at least a portion of the dampening characteristic.

The mounting arrangement of the above proximity sensor assembly may comprise a biasing member that provides the biasing characteristic, and a detection member holder attached to the detection member and having a threaded portion. Furthermore, the biasing member may be attached to the threaded portion of the detection member holder.

The switch of the above proximity sensor assembly may comprise a switch body and an actuator that is movable with respect to the switch body, and the mounting arrangement may further comprise an engaging member for engaging the actuator of the switch. When the detection member is sufficiently displaced from the home position, the engaging member may be movable away from the switch body to actuate the switch. Furthermore, the mounting arrangement may comprise a biasing member that provides the biasing characteristic, and a mount connected to the switch and having a threaded portion that is connected to the biasing member. The mounting arrangement may also comprise a detection member holder connected to the detection member, and the engaging member may be fixedly connected to the detection member holder.

The above proximity sensor assembly may include at least one damping member that provides at least a portion of the dampening characteristic. For example, the proximity sensor assembly may include at least one magnet.

As another example, the at least one damping member may comprise a pair of magnets that are positioned adjacent each other when the detection member is in the home position, and that are separable from each other when the detection member is urged away from the home position. Furthermore, the magnets may be configured to be drawn toward each other when the detection member is urged bark toward the home position by the biasing characteristic after having been displaced from the home position.

As yet another example, the at least one damping member may comprise two pairs of magnets that each comprise first and second magnets. The first and second magnets of each pair may be positioned adjacent each other when the detection member is in the home position, and the first and second magnets of each pair may be separable from each other when the detection member is urged away from the home position. Furthermore, the first and second magnets of each pair may be configured to be drawn toward each other when the detection member is urged back toward the home position by the biasing characteristic after having been displaced from the home position.

As yet another example, the at least one damping member may comprise first, second, third and fourth magnets. When the detection member is in the home position, the first and second magnets are positioned adjacent each other and the third and fourth magnets are positioned adjacent each other. When the detection member is urged away from the home position, the first and second magnets are separable from each other and the third and fourth magnets are separable from each other. Furthermore, when the detection member is urged back toward the home position by the biasing characteristic after having been displaced from the home position, the first and second magnets are configured to be drawn toward each other and the third and fourth magnets are configured to be drawn toward each other. In addition, the mounting arrangement may further comprise a spacer member, and the second and third magnets may be attached to the spacer member so that the second and third magnets are spaced apart from each other.

For the above proximity sensor assembly with four magnets, the switch may comprise a switch body, and an actuator that is movable with respect to the switch body. In addition, the mounting arrangement may further comprise a detection member holder attached to the detection member, an engaging member for engaging the actuator of the switch, and a mount connected to the switch and that receives the engaging member. Furthermore, the first magnet may be attached to the detection member holder, and the fourth magnet may be attached to the mount. When the detection member is sufficiently displaced from the home position, the engaging member may be movable away from the switch body to actuate the switch.

The mounting arrangement of the immediately preceding proximity sensor assembly may include a biasing member that provides the biasing characteristic. Furthermore, the detection member holder and the mount may each have a threaded portion, and the biasing member may be attached to the threaded portions.

The mounting arrangement of the proximity sensor assembly described in paragraph may include a detection member holder for receiving the detection member. Furthermore, one of the detection member and the detection member holder may include two projections that are receivable in two of multiple slots formed in the other of the detection member and the detection member holder so that the detection member may be oriented in any one of multiple orientations with respect to the detection member holder.

The detection member of the proximity sensor assembly of the immediately preceding paragraph may include the two projections, and the two projections may be spaced apart by 180° center to center. Furthermore, the detection member holder may include at least four slots for selectively receiving the projections.

The detection member holder of the proximity sensor assembly of the immediately preceding paragraph may include eight slots for selectively receiving the projections. Furthermore, adjacent slots may be spaced apart by 45° center to center.

According to at least one embodiment of the disclosure, a mobile work platform assembly is provided for use with a movable support assembly that is configured to move the mobile work platform assembly. The mobile work platform assembly may include a work platform sized to receive an operator, a control arrangement associated with the work platform for controlling movement of the work platform, and a proximity sensor assembly associated with the work platform. The proximity sensor assembly may include a detection member, an actuatable switch, and a movable mounting arrangement associated with the detection member and the switch. The movable mounting arrangement may include a biasing characteristic for urging the detection member toward a home position after the detection member has been displaced from the home position, and a dampening characteristic to dampen movement of the detection member. Furthermore, when the detection member is displaced from the home position, the switch is actuatable to inhibit operation of the control arrangement.

The mounting arrangement of the above mobile work platform assembly may comprise a coil spring that provides the biasing characteristic, and a detection member holder attached to the detection member and having a threaded portion. In addition, the coil spring may be attached to the threaded portion of the detection member holder.

The mounting arrangement of the above mobile work platform assembly may comprise a conical spring that provides the biasing characteristic and at least a portion of the dampening characteristic.

The proximity sensor assembly of the above mobile work platform assembly may include at least one damping member that provides at least a portion of the dampening characteristic. For example, the at least one damping member may comprise a pair of magnets that are positioned adjacent each other when the detection member is in the home position, and that are separable from each other when the detection member is urged away from the home position. Furthermore, the magnets may be configured to be drawn toward each other when the detection member is urged back toward the home position after having been displaced from the home position.

As another example, the at least one damping member of the above mobile work platform assembly may comprise first, second, third and fourth magnets. When the detection member is in the home position, the first and second magnets may be positioned adjacent each other and the third and fourth magnets may be positioned adjacent each other. When the detection member is urged away from the home position, the first and second magnets may be separable from each other and the third and fourth magnets may be separable from each other. When the detection member is urged back toward the home position after having been displaced from the home position, the first and second magnets may be configured to be drawn toward each other and the third and fourth magnets may be configured to be drawn toward each other. In addition, the mounting arrangement may further comprise a spacer member, and the second and third magnets may be attached to the spacer member so that the second and third magnets are spaced apart from each other.

The switch of the above mobile work platform assembly may comprise a switch body, and an actuator that is movable with respect to the switch body. In addition, the mounting arrangement may further comprise a detection member holder attached to the detection member, an engaging member for engaging the actuator of the switch, and a mount connected to the switch. Furthermore, the first magnet may be attached to the detection member holder, and the fourth magnet may be attached to the mount. When the detection member is sufficiently displaced from the home position, the engaging member is movable away from the switch body to actuate the switch.

A vehicle according to the disclosure may include a vehicle body, a support assembly connected to the vehicle body, and a mobile work platform assembly supported by the support assembly so that the work platform assembly is movable with respect to the vehicle body. The work platform assembly may include a work platform sized to receive an operator, a control arrangement associated with the work platform for controlling movement of the work platforms, and a proximity sensor assembly associated with the work platform. The proximity sensor assembly may include a detection member, an actuatable switch, and a movable mounting arrangement associated with the detection member and the switch. The mounting arrangement may include a biasing characteristic for urging the detection member toward a home position after the detection member has been displaced from the home position, and a dampening characteristic for dampening movement of the detection member. When the detection member is displaced from the home position, the switch is actuatable to inhibit operation of the control arrangement.

While exemplary embodiments are described above, it is not intended that these embodiments describe all possible forms according to the disclosure. In that regard, the words used in the specification are words of description rather than limitation, and it is understood that various changes may be made without departing from the spirit and scope of the disclosure. Additionally, the features of various implementing embodiments may be combined to form further embodiments according to the disclosure.

What is claimed is:

1. A proximity sensor assembly comprising:
a detection member;
a switch; and
a movable mounting arrangement associated with the detection member and the switch, the mounting arrangement including a biasing characteristic for urging the detection member toward a home position after the detection member has been displaced from the home position, and a dampening characteristic for dampening movement of the detection member;
wherein the switch is actuatable when the detection member is displaced from the home position.

2. The proximity sensor assembly of claim 1 wherein the mounting arrangement includes an extension spring to provide the biasing characteristic.

3. The proximity sensor assembly of claim 1 wherein the mounting arrangement comprises a conical spring that provides the biasing characteristic and at least a portion of the dampening characteristic.

4. The proximity sensor assembly of claim 1 wherein the mounting arrangement comprises a biasing member that provides the biasing characteristic, and a detection member holder attached to the detection member and having a threaded portion, and wherein the biasing member is attached to the threaded portion of the detection member holder.

5. The proximity sensor assembly of claim 1 wherein the switch comprises a switch body, and an actuator that is movable with respect to the switch body, and the mounting arrangement further comprises an engaging member for engaging the actuator of the switch, wherein, when the detection member is sufficiently displaced from the home position, the engaging member is movable away from the switch body to actuate the switch.

6. The proximity sensor assembly of claim 5 wherein the mounting arrangement comprises a biasing member that provides the biasing characteristic, and a mount connected to the switch and having a threaded portion that is connected to the biasing member.

7. The proximity sensor assembly of claim 5 wherein the mounting arrangement comprises a detection member holder connected to the detection member, and wherein the engaging member is fixedly connected to the detection member holder.

8. The proximity sensor assembly of claim 1 wherein the proximity sensor assembly includes at least one damping member that provides at least a portion of the dampening characteristic.

9. The proximity sensor assembly of claim 8 wherein the at least one damping member comprises at least one magnet.

10. The proximity sensor assembly of claim 8 wherein the at least one damping member comprises a pair of magnets that are positioned adjacent each other when the detection member is in the home position, and that are separable from each other when the detection member is urged away from the home position, and wherein the magnets are configured to be drawn toward each other when the detection member is urged back toward the home position by the biasing characteristic after having been displaced from the home position.

11. The proximity sensor assembly of claim 8 wherein the at least one damping member comprises first, second, third and fourth magnets, wherein, when the detection member is in the home position, the first and second magnets are positioned adjacent each other and the third and fourth magnets are positioned adjacent each other, wherein, when the detection member is urged away from the home position, the first and second magnets are separable from each other and the third and fourth magnets are separable from each other, and wherein, when the detection member is urged back toward the home position by the biasing characteristic after having been displaced from the home position, the first and second magnets are configured to be drawn toward each other and the third and fourth magnets are configured to be drawn toward each other.

12. The proximity sensor assembly of claim 11 wherein the mounting arrangement further comprises a spacer member, wherein the second and third magnets are attached to the spacer member so that the second and third magnets are spaced apart from each other.

13. The proximity sensor assembly of claim 12 wherein the switch comprises a switch body, and an actuator that is movable with respect to the switch body, wherein the mounting arrangement further comprises a detection member holder attached to the detection member, an engaging member for engaging the actuator of the switch, and a mount connected to the switch and that receives the engaging member, wherein the first magnet is attached to the detection member holder, and the fourth magnet is attached to the mount, and wherein when the detection member is sufficiently displaced from the home position, the engaging member is movable away from the switch body to actuate the switch.

14. The proximity sensor assembly of claim 13 wherein the mounting arrangement includes a biasing member that provides the biasing characteristic, the detection member holder and the mount each have a threaded portion, and the biasing member is attached to the threaded portions.

15. The proximity sensor assembly of claim 1 wherein the mounting arrangement includes a detection member holder for receiving the detection member, and wherein one of the detection member and the detection member holder includes one or more projections that are each selectively receivable in one of multiple slots formed in the other of the detection member and the detection member holder so that the detection member may be oriented in any one of multiple orientations with respect to the detection member holder.

16. The proximity sensor assembly of claim 1 wherein the mounting arrangement includes a detection member holder for receiving the detection member, wherein one of the detection member and the detection member holder includes two projections that are selectively receivable in two of eight slots formed in the other of the detection member and the detection member holder so that the detection member may be oriented in any one of multiple orientations with respect to the detection member holder, and wherein the projections are spaced apart 180° center to center, and adjacent slots are spaced apart by 45° center to center.

17. A mobile work platform assembly for use with a movable support assembly that is configured to move the mobile work platform assembly, the mobile work platform assembly comprising:
a work platform sized to receive an operator;
a control arrangement associated with the work platform for controlling movement of the work platform; and
a proximity sensor assembly associated with the work platform and including a detection member, an actuatable switch, and a movable mounting arrangement associated with the detection member and the switch, the mounting arrangement including a biasing characteristic for urging the detection member toward a home position after the detection member has been displaced from the home position, and a dampening characteristic for dampening movement of the detection member, wherein when the detection member is displaced from the home position, the switch is actuatable to inhibit operation of the control arrangement.

18. The mobile work platform assembly of claim 17 wherein the mounting arrangement comprises a coil spring that provides the biasing characteristic, and a detection member holder attached to the detection member and having a threaded portion, and wherein the coil spring is attached to the threaded portion of the detection member holder.

19. The mobile work platform assembly of claim 17 wherein the mounting arrangement comprises a conical spring that provides the biasing characteristic and at least a portion of the dampening characteristic.

20. A vehicle comprising:
a vehicle body;
a support assembly connected to the vehicle body; and
a mobile work platform assembly supported by the support assembly so that the work platform assembly is movable with respect to the vehicle body, the work platform assembly including a work platform sized to receive an operator, a control arrangement associated with the work platform for controlling movement of the work platform, and a proximity sensor assembly associated with the work platform and including a detection member, an actuatable switch, and a movable mounting arrangement associated with the detection member and the switch, the movable mounting arrangement including a biasing characteristic for urging the detection member toward a home position after the detection member has been displaced from the home position, and a dampening characteristic for dampening movement of the detection member, wherein when the detection member is displaced from the home position, the switch is actuatable to inhibit operation of the control arrangement.
